(19) United States
(12) Patent Application Publication
(10) Pub. No.: US 2026/0231544 A1
(43) Pub. Date: Aug. 6, 2026

(54) IMAGE SENSING DEVICE AND IMAGING DEVICE INCLUDING THE SAME

(71) Applicant: SK hynix Inc., Icheon-si (KR)

(72) Inventor: Woo Sung SHIM, Icheon-si (KR)

(21) Appl. No.: 19/228,541

(22) Filed: Jun. 4, 2025

(30) Foreign Application Priority Data
Feb. 4, 2025 (KR) 10-2025-0013671

(51) Int. Cl. H10F 39/00; H04N 25/59

(52) U.S. Cl. CPC H10F 39/8037; H04N 25/59

(57) ABSTRACT

An image sensing device is provided to a driver transistor comprising a first electrode to which a power voltage is applied, a gate electrode connected to a floating diffusion region, and a second electrode; a first selection transistor comprising a fourth electrode connected to the second electrode of the driver transistor, a gate electrode to which a first selection control signal is applied, and a fifth electrode; a second selection transistor comprising a sixth electrode connected to the fifth electrode of the first selection transistor, a gate electrode to which a second selection control signal is applied, and a seventh electrode connected to an output signal line; and a boosting capacitor disposed between the fifth electrode of the first selection transistor and the floating diffusion region and configured to control a capacitance of the floating diffusion region.

This application claims priority to and the benefit of Korean Patent Application No. 10-2025-0013671, filed on Feb. 4, 2025, the disclosure of which is incorporated herein by reference in its entirety.

### TECHNICAL FIELD

Embodiments of the present disclosure relate to an image sensing device and an imaging device including the same.

### BACKGROUND

With development of information and communication industry and digitalization of electronic devices, image sensors with improved performance are being used in various fields such as digital cameras, camcorders, mobile phones, PCS (personal communication systems), game devices, security cameras, and medical micro cameras. Typically, an image sensor has a pixel region including a photodiode and a peripheral region. A unit pixel includes a photodiode and a transfer transistor. The transistor is arranged between the photodiode and a floating diffusion region to transfer charges generated by the photodiode to the floating diffusion region.

### SUMMARY

Some implementations of the disclosed technology provide an image sensing device configured to selectively control the capacitance of a boosting capacitor (or a floating diffusion region).

Some implementations of the disclosed technology provide a method of operating an image sensing device configured to selectively control the capacitance of a boosting capacitor (or a floating diffusion region).

In one aspect, an image sensing device is provided to include a photoelectric conversion element configured to generate photocharges corresponding to an incident light; a floating diffusion region coupled to the photoelectric conversion element and configured to receive and store the photocharges; a driver transistor comprising a first electrode to which a power voltage is applied, a gate electrode connected to a floating diffusion region, and a second electrode; a first selection transistor comprising a fourth electrode connected to the second electrode of the driver transistor, a gate electrode to which a first selection control signal is applied, and a fifth electrode; a second selection transistor comprising a sixth electrode connected to the fifth electrode of the first selection transistor, a gate electrode to which a second selection control signal is applied, and a seventh electrode connected to an output signal line; and a boosting capacitor disposed between the fifth electrode of the first selection transistor and the floating diffusion region and configured to control a capacitance of the floating diffusion region.

A method of operating an image sensing device according to one embodiment, may include turning on a reset transistor and a transmission transistor and resetting a photodetector in a first time period; operating, in a second time period, a photodetector to generate and accumulate photocharges in the photodetector corresponding to an incident light; resetting a floating diffusion region in a third time period; operating, in a fourth time period, at least one selection transistor and a reverse selection transistor in a fourth time period to output a voltage of the floating diffusion region which has been reset; operating, in a fifth time period, the transmission transistor to allow the photocharges to move from the photodetector to the floating diffusion region; and in a sixth time period, operating the at least one selection transistor and turning off the reverse selection transistor to output the voltage of the floating diffusion region to which the photocharges are transferred from the photodetector.

According to the embodiments, in the time period in which photocharges are transmitted to the floating diffusion region from the photodetector, the boosting capacitor and the boosting control line may be additionally disposed to form the capacitance in the floating diffusion region. Due to that, in the time period in which the photocharges are transmitted to the floating diffusion region, the capacitance of the floating diffusion region may become high. Accordingly, the movement of photocharges from the photodetector to the floating diffusion region may be performed smoothly.

In the time period in which the photocharges of the floating diffusion region read out, the capacitance of the floating diffusion region can become high even if the boosting control signal is not applied by the boosting capacitor. In this case, it could be difficult to implement HCG mode.

According to the embodiments, the image sensing device may provide the first row selection transistor connected to the driver transistor, the second row selection transistor connected to the first row selection transistor and the output signal line, and the reverse row selection transistor connected to the first and second row selection transistors. Accordingly, in the time period in which the photocharges of the floating diffusion region read out, the boosting capacitor may be controlled to have Miller capacitance, thereby lowing the capacitance of the floating diffusion region.

With the suggested implementations of the disclosed technology, it is possible to implement the HCG mode.

Various implementations of the disclosed technology will be described in the detailed description. However, it should be understood that the detailed description are given by illustration only, since variations and improvements of the disclosed embodiments and other embodiments may be made based on what is described or illustrated in this document.

### DETAILED DESCRIPTION

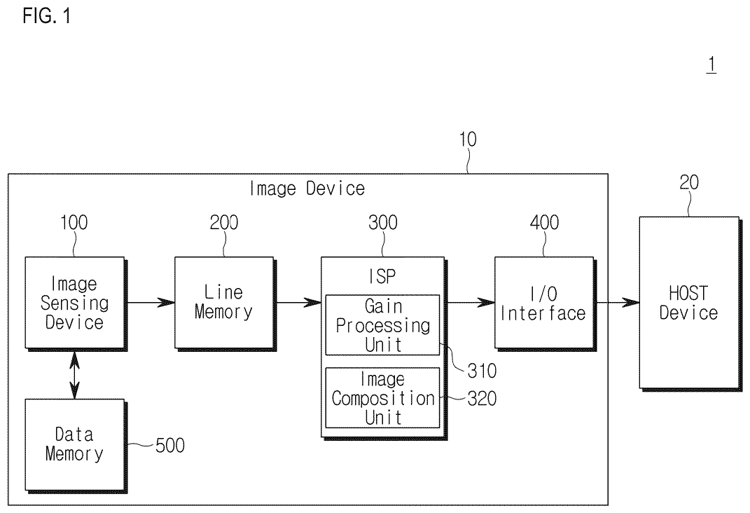

FIG. 1 is a block view of an imaging system based on some implementations of the disclosed technology.

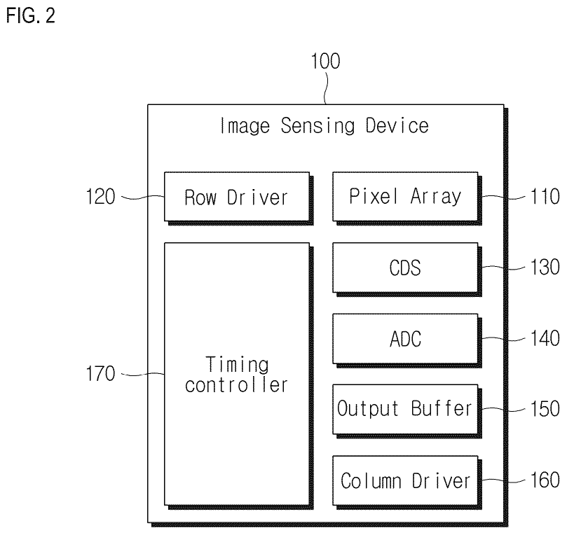

FIG. 2 shows an example of the image sensing device shown in FIG. 1 based on some implementations of the disclosed technology.

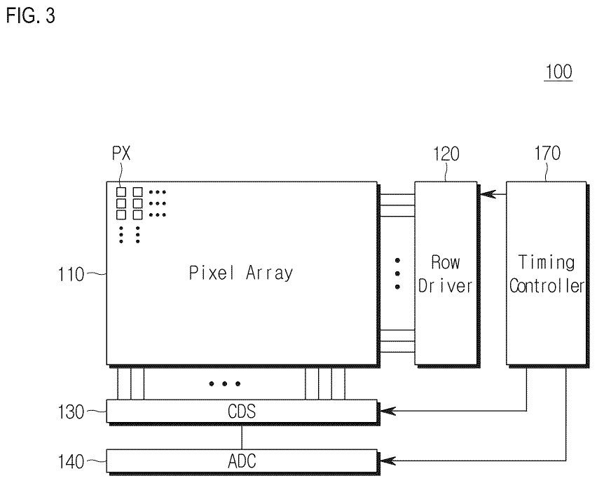

FIG. 3 is an example of a block diagram of the image sensing device shown in FIG. 1 based on some implementations of the disclosed technology.

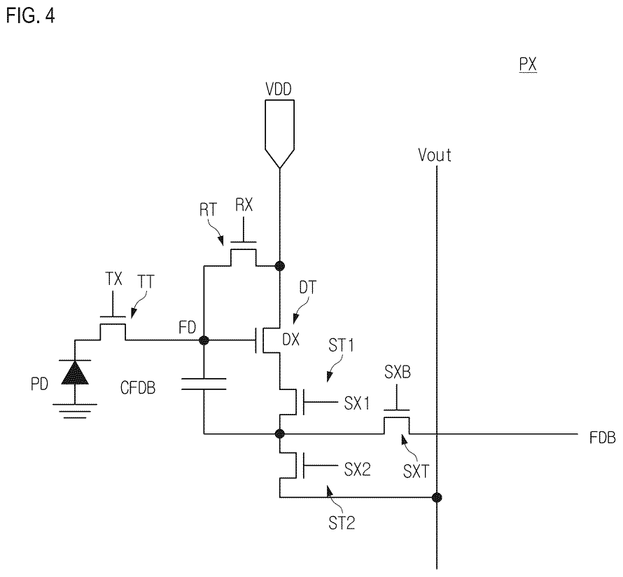

FIG. 4 is an equivalent circuit of a pixel array shown in FIG. 3.

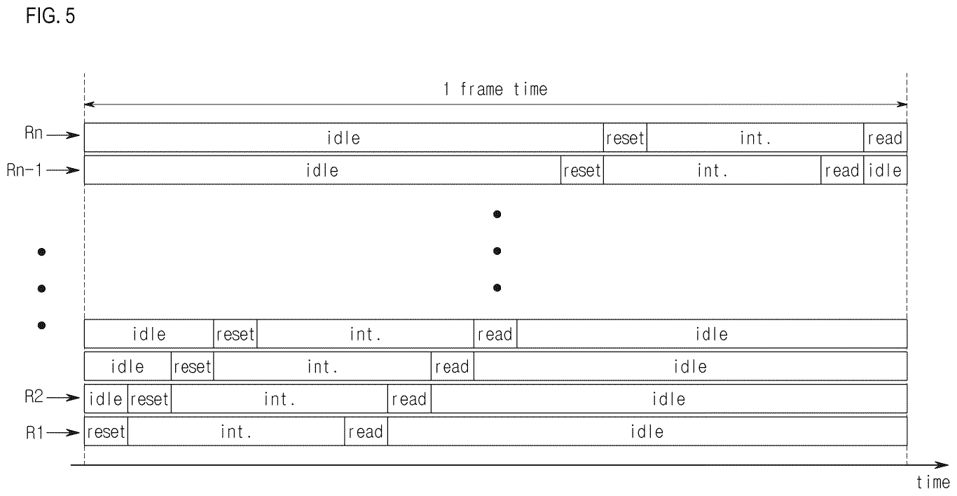

FIG. 5 is an example of a timing diagram of multiple pixels based on some implementations of the disclosed technology.

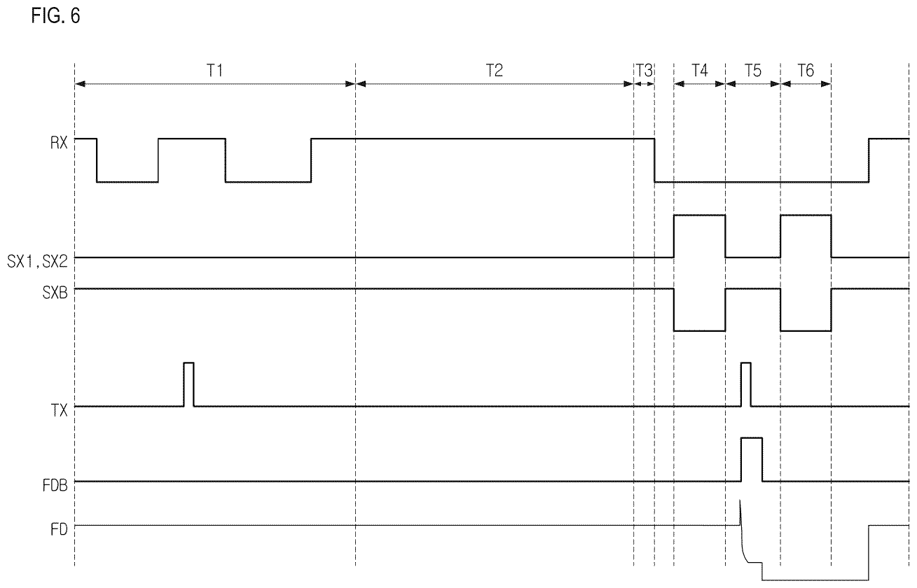

FIG. 6 is an example of a timing diagram of one pixel shown in FIG. 5.

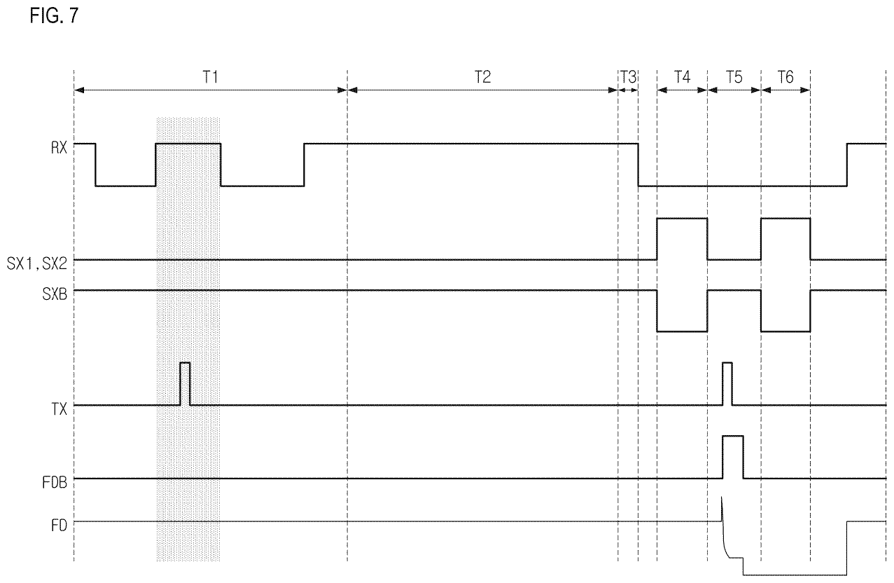

FIG. 7 is an example of a timing diagram including a first period shown in FIG. 6.

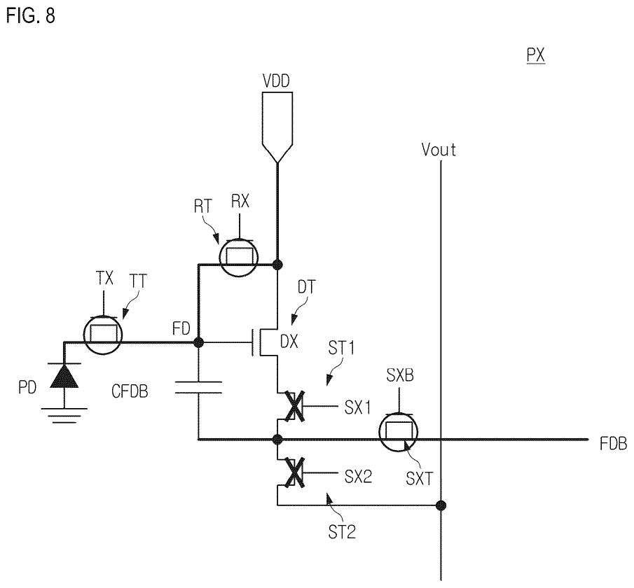

FIG. 8 is an equivalent circuit showing an operation of transistors in the first period shown in FIG. 6.

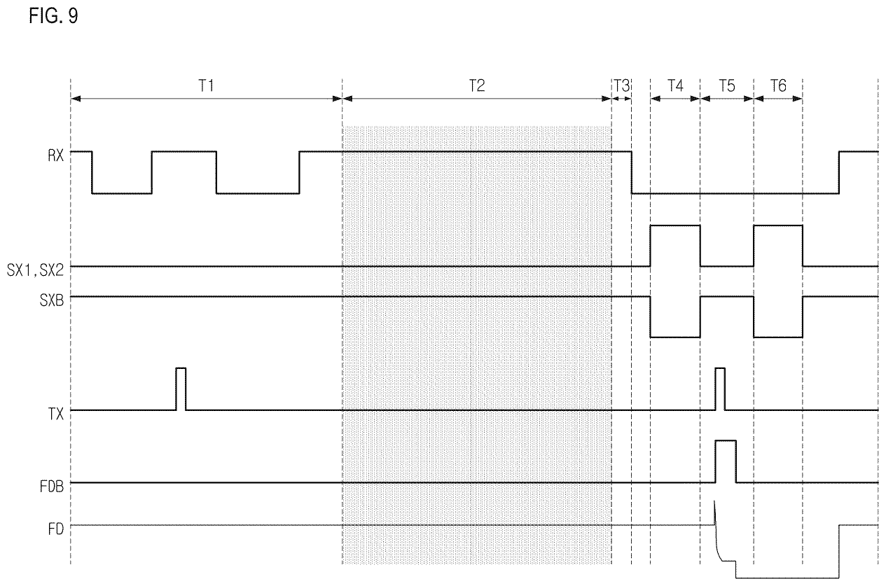

FIG. 9 is an example of a timing diagram including a second period shown in FIG. 6.

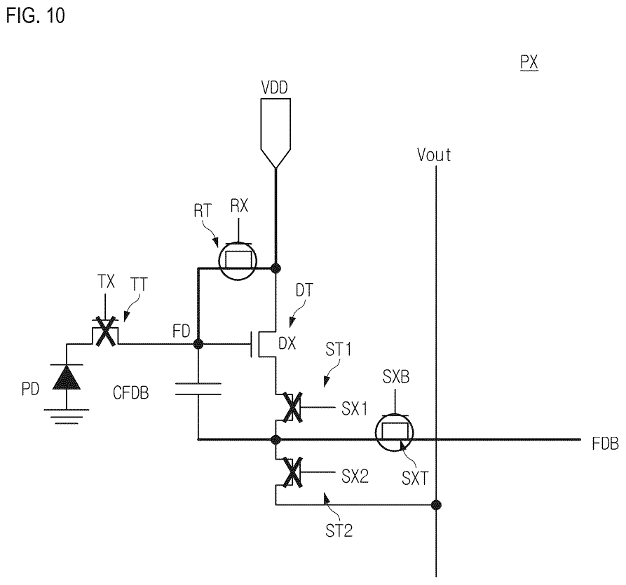

FIG. 10 is an equivalent circuit showing an operation of transistors in a second period shown in FIG. 6.

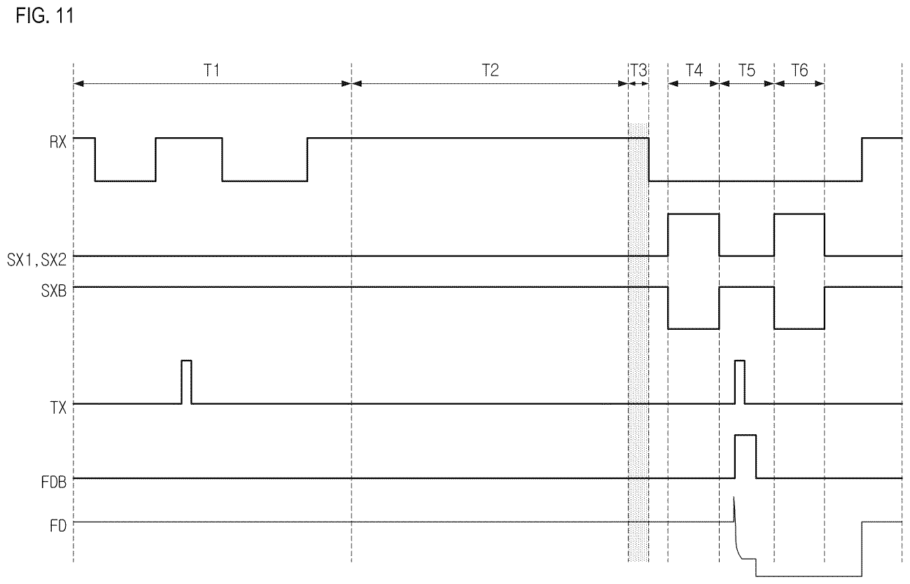

FIG. 11 is an example of a timing diagram including a third period shown in FIG. 6.

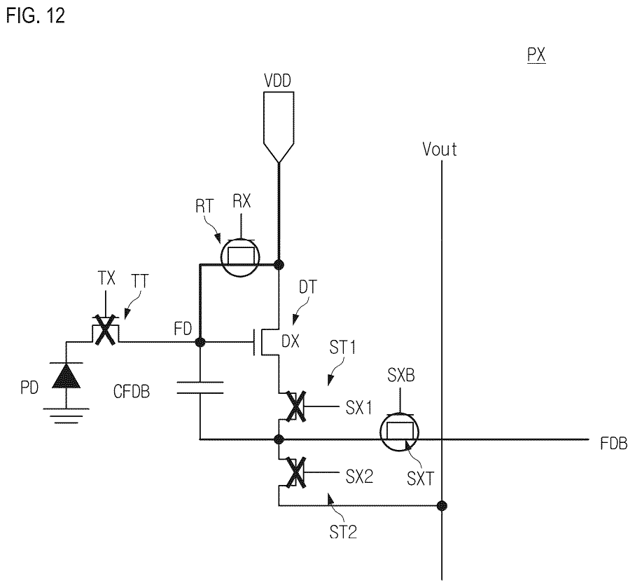

FIG. 12 is an equivalent circuit showing an operation of transistors in a third period shown in FIG. 6.

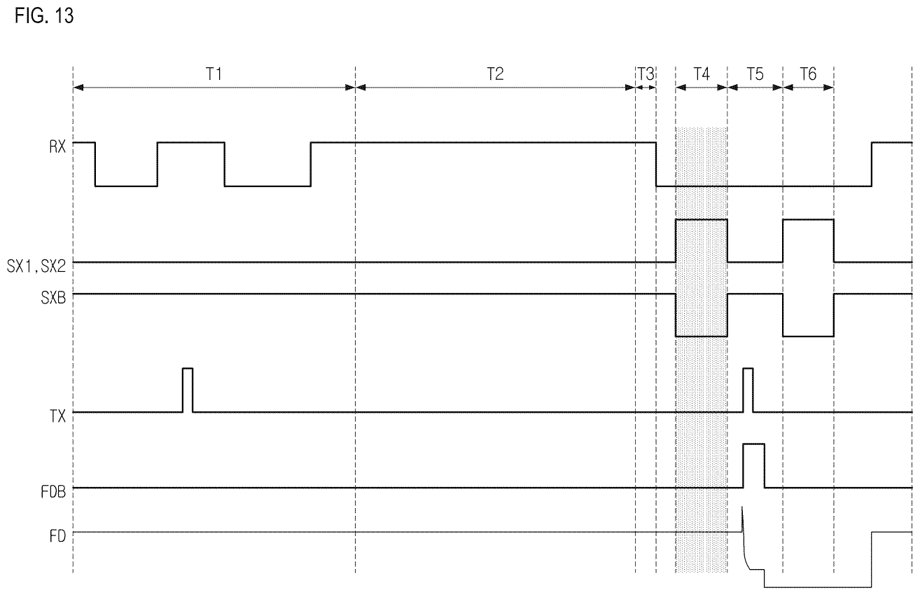

FIG. 13 is an example of a timing diagram including a fourth period shown in FIG. 6.

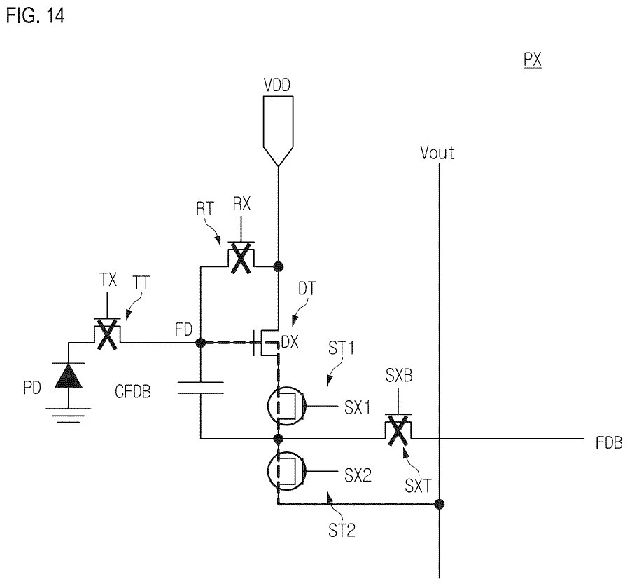

FIG. 14 is an equivalent circuit showing an operation of transistors in a fourth period shown in FIG. 6.

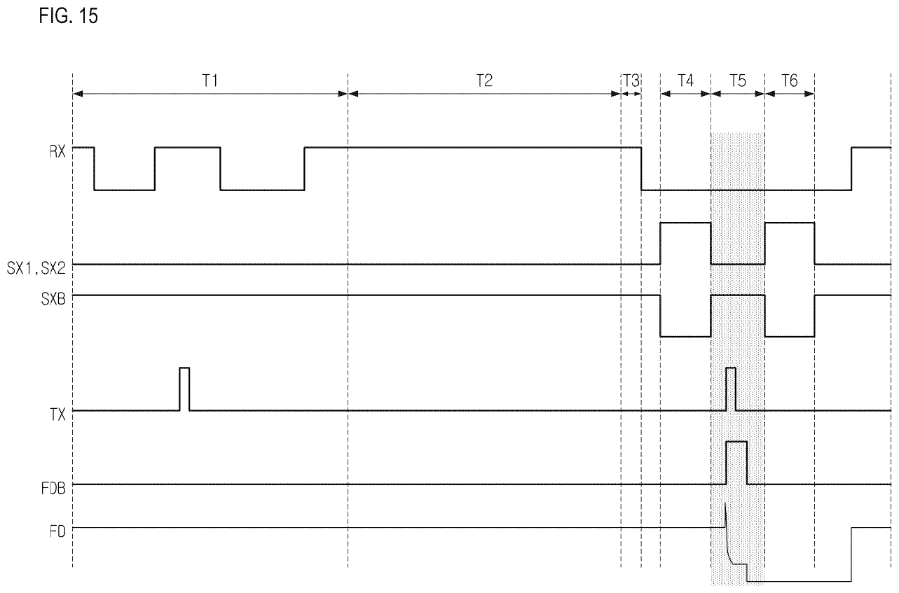

FIG. 15 is an example of a timing diagram including a fifth period shown in FIG. 6.

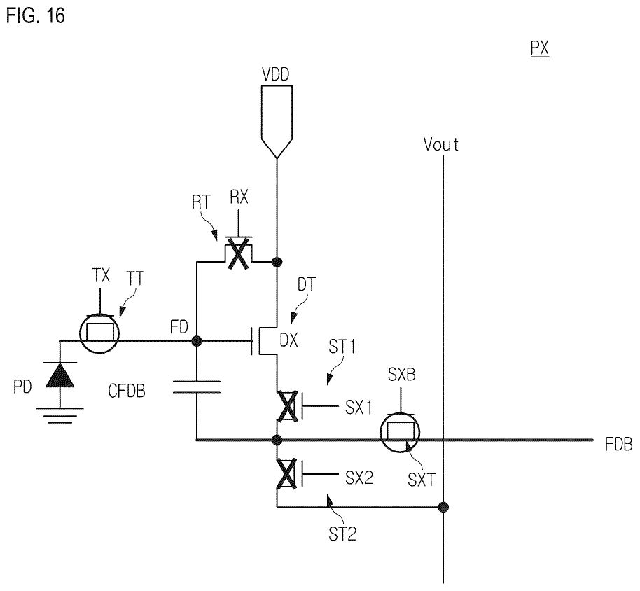

FIG. 16 is an equivalent circuit showing an operation of transistors in a fifth period shown in FIG. 6.

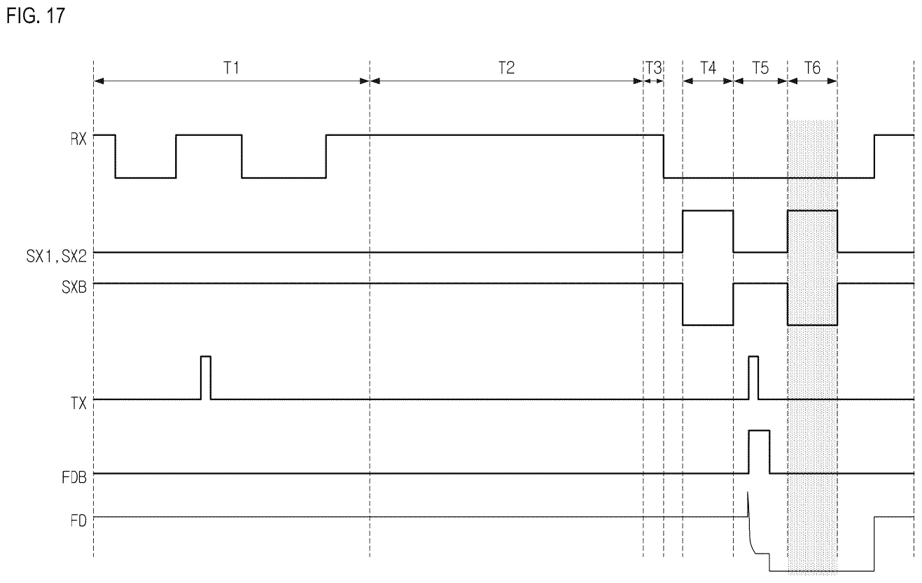

FIG. 17 is an example of a timing diagram including a sixth period shown in FIG. 6.

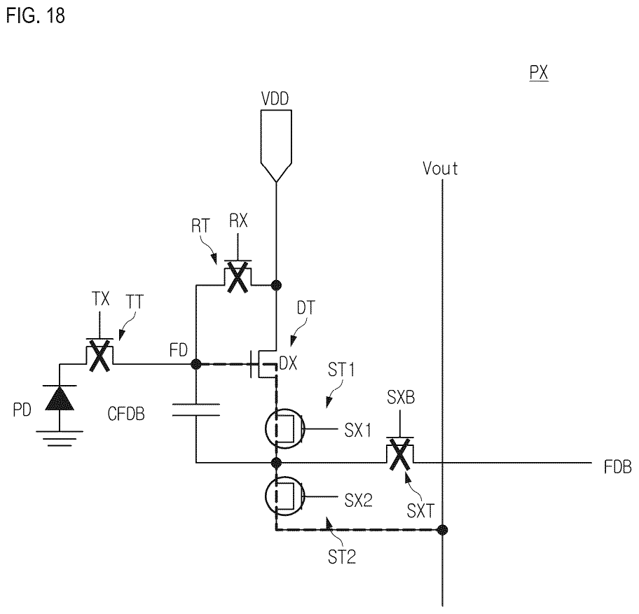

FIG. 18 is an equivalent circuit showing an operation of transistors in a sixth period shown in FIG. 6.

### DESCRIPTION OF SPECIFIC EMBODIMENTS

Description will now be given in detail according to exemplary embodiments disclosed herein, with reference to the accompanying drawings.

FIG. 1 is a block view of an imaging system based on some implementations of the disclosed technology. FIG. 2 shows the image sensing device shown in FIG. 1.

Referring to FIG. 1, an imaging system 1 may refer to or include a device such as a digital still camera configured to shoot still images or a digital video camera configured to shoot moving images, as well as a device configured to detect motion. For example, an imaging device 10 may be implemented as a digital signal lens reflex DSLR camera, a mirrorless camera, or a mobile phone (especially, a smartphone), but the imaging device 10 is not limited thereto. The imaging device 10 may include a device configured to shoot a subject and generate an image by including a lens and an imaging element.

The imaging system 1 may include an imaging device 10 and a host device 20.

The imaging device 10 may include an image sensing device 100; a line memory 200, ISP (image signal processor) 300, an input/output interface (I/O interface) 400, and a data memory 500.

The image sensing device 100 may be or include CIS (Complementary Metal Oxide Semiconductor Image Sensor) configured to convert an optical signal into an electrical signal. The ISP 300 may control the overall operation of the image sensing device 100 such as on/off, operation mode, operation timing, and/or sensitivity. The image sensing device 100 may convert the optical signal into the electrical signal to transmit image data to the line memory 200 based on the control of the ISP 300.

The line memory 200 may include volatile memory (e.g., DRAM, SRMA) and/or non-volatile memory (e.g., flash memory).

The line memory 200 may be configured to receive and store image data from the image sensing device 100, and transmit the stored data to the ISP 300 based on the control of the ISP 300.

The ISP 300 may be configured to perform image signal processing on the image data stored in the line memory 200. The ISP 300 may be configured to perform image signal processing to reduce noise in image data and improve image quality, such as gamma correction, color filter array interpolation, color matrix, color correction, color enhancement, and lens distortion correction.

To generate HDR image, the ISP 300 may include a gain processing unit 310, and an image synthesis unit 320.

The gain processing unit 310 may be configured to determine a gain to be operated on (e.g., multiplication operation) for image data. The gain processing unit 310 may determine a gain based on the difference in conversion gain between HCG (High Conversion Gain) mode and LCD (Low Conversion Gain) mode, and provide the determined gain to an image synthesis unit 320.

Each pixel of the pixel array 110 may operate in the HCG mode or the LCG mode, and the mode of each pixel may be determined by the intensity (or illuminance) of light incident on each pixel.

The image synthesis unit 320 may be configured to synthesize an HDR image corresponding to a high dynamic range by using the image data of pixels operating in the HCG mode and/or image data of pixels operating in the LCG mode.

The ISP 300 may transmit the image data processed by the image signal (i.e., HDR image) to the input/output interface 400.

In some implementations, the gain processing unit 310 and the image synthesis unit 320, which are configured to generate the HDR image, may be provided in the image sensing device 100 instead of the ISP 300.

The input/output interface 400 may be configured to perform communication with the host device 20 and transmit the image data processed by the image signal to the host device 20.

The host device 20 may be or include a processor (e.g., an application processor) configured to process image data for processed images received from the imaging device 10, a memory (e.g., a non-volatile memory) configured to store image data, or a display device (e.g. a liquid crystal display LCD) configured to visually output image data.

The data memory 500 may store image data (Data_PX) in digital format converted from an analog-digital converter 140.

FIG. 2 shows an example of an image sensing device shown in FIG. 1 based on some implementations of the disclosed technology.

Referring to FIG. 2, the image sensing device 100 may include a pixel array 110, a row driver 120, a correlate double sampler CDS 130, an analog-digital converter ADC 140, an output buffer 150, a column driver 160, and a timing controller 170. Here, the components of the image sensing device 100 are exemplary and some of them may be added or omitted depending on the implementations.

The pixel array 110 may include a plurality of image pixels arranged in multiple rows and columns. In one embodiment, the plurality of image pixels may be arranged in a two-dimensional pixel array including rows and columns. In another embodiment, the plurality of image pixels may be arranged in a three-dimensional pixel array. The plurality of image pixels may convert an optical signal into an electrical signal on a pixel unit basis or a pixel group basis, and image pixels in a pixel group may share at least predetermined internal circuit. The pixel array 110 may receive a pixel control signal include a low selection signal, a pixel reset signal, and a transmission signal from the row driver 120. By the pixel control signal, the corresponding pixel of the pixel array 110 may be activated to perform an operation corresponding to the low selection signal, the pixel reset signal and the transmission signal. Each image pixel may detect incident light by generating a photocharge corresponding to the intensity (or illuminance) of incident light and generating an electrical signal with a size corresponding to the amount of generated photocharge. For convenience of description, an image pixel may be referred to as a pixel.

The row driver 120 may be configured to activate the pixel array to perform a specific operation for pixels included in the corresponding low based on commands and control signals supplied by the timing controller 170.

In one embodiment, the correlate double sampler 130 may be configured to perform sequentially sampling and holding for a reference signal and an image signal which are provided to each of the column lines from the pixel array 110. That is, the correlate double sampler 130 may sample and hold the levels of the reference and image signal corresponding to each of the columns of the pixel array 110.

Based on the control signal from the timing controller 180, the correlate double sampler 130 may transmit the reference signal and image signal of each column to the ADC 140 as the correlate double sampling signal.

The ADC 140 may convert the correlate double sampling signal for each column output from the correlate double sampler 130 into a digital signal, and then output image data. In one embodiment, the ADC 140 may convert the correlate double sampling signal generated by the correlate double sampler 130 for each column into a digital signal and output the converted digital signal.

The ADC 140 may include a plurality of column counters corresponding to the columns of the pixel array 110, respectively. Each column of the pixel array 110 may be connected to each column counter, and image data may be generated by converting the correlate double sampling signal corresponding to each column into a digital signal, using the column counters.

The output buffer 150 may be configured to temporarily hold and output the image data of each column provided from the ADC 140. The output buffer 150 may temporarily store the image data output from the ADC 140 based on the control signal of the timing controller 170.

The column driver 160 may be configured to select the column of the output buffer 150 based on the control signal of the timing controller 170, and control the output buffer 150 to sequentially output the image data temporarily stored in the selected column of the output butter 150.

The timing controller 170 may be configured control at least one of the row driver 120, the correlate double sampler 130, the ADC 140, the output buffer 150, and the column driver 160.

The timing controller 170 may provide clock signals required for the operations of the components of the image sensing device 100, control signals for timing control, and address signals for selecting rows and columns to at least one of the row driver 120, the correlate double sampler 130, the ADC 140, the output buffer 150, and the column driver 160. According to one embodiment, the timing controller 170 may include a logic control circuit, a phase lock loop PLL circuit a timing control circuit, and a communication interface circuit.

FIG. 3 is an example of a block diagram of the image sensing device shown in FIG. 1 based on some implementations of the disclosed technology. In FIG. 3, the pixel array 110 is illustrated with the pixels (PXs). In various implementations, the pixel array 110 is supported by a substrate by suitable integrated circuit fabrication processes such as a complementary metal-oxide semiconductor (CMOS) process to construct the pixel array as a CMOS pixel array.

Referring to FIG. 3, the pixel array 110 may include a plurality of pixels (PXs). The pixels may be arranged in a matrix format along the row and column directions, but the embodiments of the present disclosure are not limited thereto. The pixels PX may include a red pixel, a green pixel, and a blue pixel, but the embodiments of the preset disclosure are not limited thereto. The pixels may further include a white pixel or an infrared pixel.

The plurality of pixels PX may be electrically connected to the row driver 120. The plurality of pixels may be connected to control lines extending from the row driver 120, respectively. The control lines may be transmission lines shown in FIG. 3 or boosting control lines, but the embodiments of the present disclosure are not limited thereto.

The timing controller 170, the correlate dual sampler 130, and the ADC 140, which are shown in FIG. 3, are the same as the those described referring to FIG. 2, so repeated description will be omitted.

FIG. 4 is an equivalent circuit of a pixel array shown in FIG. 3.

Referring to FIG. 4, the circuit view of the pixel may correspond to an equivalent circuit of each pixel PX included in the pixel array (110, see FIG. 3).

The pixel PX may include a photodetector PD, a transfer transistor TT, a reset transistor RT, a floating diffusion region FD, driver transistor DT, and a selection transistor ST. With the four transistors included in the pixel PX, the pixel may be referred to as a 4-transistor 4TR pixel.

The photodetector PD may be configured to generate and accumulate a photocharge corresponding to the intensity of incident light. For example, the photodetector PD may be implemented as a photodiode, a phototransistor, a photogate, a pinned photodiode, or a combination thereof. When the photodetector PD is implemented as a photodiode, it may be a region that is doped with an impurity of a second conductivity type (e.g., N-type) within a substrate having a first conductivity type (e.g., P-type).

Each of the transistors TT, RT, DT, ST1, ST2, and SBT may have a first electrode and a second electrode. hereinafter, the first electrode and the second electrode may be referred to as a source electrode and a drain electrode, respectively.

The transmission transistor TT may be connected between the photodetector PD and the floating diffusion region FD. The transmission transistor TT may be turned on or off in response to a transmission control signal TX applied to the gate electrode, and the turned-on transmission transistor TT may transmit the photocharges accumulated in the photodetector PD to the floating diffusion region FD. The source electrode of the transmission transistor TT may be connected to the photodetector PD and the drain electrode thereof may be connected to the floating diffusion region FD.

The reset transistor RT may be connected between a power voltage VDD and the floating diffusion region FD, and configured to reset the voltage of the floating diffusion region FD to the power supply voltage VDD in response to a reset control signal RX applied to the gate electrode.

The floating diffusion region FD may be configured to accumulate the photocharge transmitted from the transmission transistor TT. For example, the floating diffusion region FD may be a region doped with a second conductivity type (e.g., N-type) impurity within a first conductivity type (e.g., P-type) substate, and the substate and the dopped region may be modeled as a junction capacitor. The floating diffusion region FD may be connected to the gate electrode of the driver transistor DT, the drain electrode of the transmission transistor TT, and the drain electrode of the reset transistor RT. A floating diffusion electrode may be disposed on the floating diffusion region FD.

The driver transistor DT may be connected between the power voltage VDD and the selection transistor ST, and configured to amplify the change in electric potential of the floating diffusion region FD configured to receive the photocharges accumulated in the photodetector PD, and transmit it to the selection transistor ST. The gate electrode of the driver transistor DT may be connected to the floating diffusion region FD, the power voltage VDD may be applied to the source electrode, and the drain electrode may be connected to the source electrode of the selection transistor ST.

Two selection transistors ST1 and ST2 may be provided. The first selection transistor ST1 may be disposed between the driver transistor DT and the boosting capacitor CFDB, between the driver transistor DT and the second selection transistor ST2, and between the driver transistor DT and the reverse selection transistor SXT. The first selection transistor ST1 may be turned on by a first selection control signal SX1 applied to the gate electrode, and output the electric signal transmitted from the driver transistor DT to the second selection transistor ST2. The source electrode of the first selection transistor ST1 may be connected to the drain electrode of the driver transistor DT. The source electrode of the first selection transistor ST1 may be connected to the source electrode of the second selection transistor ST2.

The second selection transistor ST2 may connect the first selection transistor ST1 and the output signal line. The second selection transistor ST2 may be turned on by the second selection control signal SX2 applied to the gate electrode and output the electric signal transmitted from the first selection transistor ST2 to the output signal line. The source electrode of the second selection transistor ST2 may be connected to the drain electrode of the first selection transistor ST1. The drain electrode of the second selection transistor ST2 may be connected to the output signal line.

For example, the first selection control signal SX1 and the second selection control signal SX2 may be the same signal. In this instance, the second selection transistor ST1 and the second selection transistor ST2 may be turned on or off simultaneously. However, the embodiments of the present disclosure are not limited thereto.

The reverse selection transistor SXT may connect the first selection transistor ST1 and the boosting control line. The reverse selection transistor SXT may be turned on by a reverse selection control signal SXB applied to the gate electrode, and provide a boosting control signal FDB to the boosting capacitor CFDB. The source electrode of the reverse selection transistor SXT may be connected to the boosting control line. The drain electrode of the reverse selection transistor SXT may be connected to the other electrode of the boosting capacitor CFDB.

The boosting capacitor CFDB may be disposed between the floating diffusion region FD and the node between the first selection transistor ST1 and the second selection transistor ST2. One electrode of the boosting capacitor CFDB may be connected to the floating diffusion region FD and other electrode thereof may be connected to the node between the first selection transistor ST1 and the second selection transistor ST2. The boosting capacitor CFDB may be configured to control capacitance of the floating diffusion region.

The voltage of the floating diffusion region FD may be determined based on the amount of the photocharges transmitted through the transmission transistor TT. The greater the amount of the photocharges, the lower the voltage of the floating diffusion region FD. The floating diffusion region FD (or floating diffusion electrode) may be connected to the boosting capacitor CFDB. The capacitance of the floating diffusion region FD may equal to the sum of the parasitic capacitance between the floating diffusion region FD (or floating diffusion electrode) and the surrounding electrodes and the boosting capacitance of the boosting capacitor CFDB. In the implementations of the disclosed technology, the boosting capacitance of the boosting capacitor CFDB may vary based on the parasitic capacitance between the electrodes adjacent to the boosting capacitor CFDB, the size of the boosting control signal FDB, and/or the Miller Effects as further discussed later in this document. For example, as the boosting control signal FDB becomes large, the boosting capacitance of the boosting capacitor CFDB may increase. In the capacitance of the floating diffusion region FD, the extent to which the boosting capacitance of the boosting capacitor CFDB occupies may be large. In addition, the capacitance of the floating diffusion region FD may be inversely proportional to the conversion gain CG.

FIG. 5 is an example of a timing diagram of multiple pixels based on some implementations of the disclosed technology.

FIG. 5 shows the timing diagram of each pixel row (R1, R2, . . . , Rn−1, and Rn) of the pixel array (110, see FIG. 3). In FIG. 5, as one example, the start and end points of the timing of all pixel rows are shown as 1 frame time.

As shown in FIG. 5, the pixel operation of the pixel in a first pixel row R1 may include a reset time, a light irradiation time (int. time), a rea time, and an idle time. In the first pixel row R1, the reset time, the initialization time (int. time), the read time, and the idle time may be sequentially performed. After the reset time of the first pixel row R1 proceeds, the reset time, the initialization time (int. time), the read time, and the idle time of the second pixel row R2 may be sequentially performed. After the rest time of the second pixel row R2 proceeds, the reset time, the initialization time (int. time), the read time, and the idle time of the third pixel row R3 may be sequentially performed. In this manner, from the first pixel row R1 to the nth pixel row Rn, the reset time, the initialization time (int. time), the read time, and the idle time of each of the first pixel row R1 to the nth pixel row Rn may be sequentially performed.

FIG. 6 is an example of a timing diagram of one pixel shown in FIG. 5. Hereinafter, the reset time may be referred to as a first time T1, the light irradiation time as a second time T2, the read time as third to sixth times (T3, T4, T5, and T6). The third time T3 may be a FD reset time, the fourth time T4 may be a first read out time, the fifth time T5 may be a boosting time, and the sixth time T6 may be a second read out time. The first time T1 may be a PD reset time.

Referring to FIGS. 4 to 6, the operations of the pixel PX over time are explained. In this regard, FIG. 6 shows the voltages of a first selection control signal SX1, a second selection control signal SX2, a reset control signal RX, a transmission control signal TX, a boosting control signal FDB, a reverse selection control signal SBX, and a floating diffusion region FD. Each of the first selection SX1, the second selection control signal SX2, the reset control signal RX, the transmission control signal TX, the boosting control signal FDB, the reverse selection control signal SBX, and the floating diffusion region FD may have an activation voltage (e.g., high voltage) or a deactivation voltage (e.g., low voltage). When each of the first selection SX1, the second selection control signal SX2, the reset control signal RX, the transmission control signal TX, and the reverse selection control signal SBX has an activation voltage, its corresponding transistor ST1, ST2, RT, TT, and S may be turned on. In contrast, when each the first selection control signal SX1, the second selection control signal SX2, the reset control signal RX, the transmission control signal TX, and the reverse selection control signal SBX has a deactivation voltage, its corresponding transistor ST1, ST2, RT, TT, and SBT may be turned off.

Hereinafter, the operation of the pixel PX in each time period T1 to T5 will be described based on the circuit diagram and waveform diagram of the pixel PX.

FIG. 7 is an example of a timing diagram including a first period shown in FIG. 6 and FIG. 8 is an equivalent circuit showing the operation of transistors in the first period.

Referring to FIGS. 7 and 8, in the first time period T1, the reset control signal RX and the transmission control signal TX have activation voltages, respectively, and the rest transistor RT and the transmission transistor TT may be turned on. The voltage of the photodetector PD may be reset to a power voltage VDD. In the first time period T1, the first and second selection control signals SX1 and SX2 may have deactivation voltages, respectively, and the first and second selection transistors ST1 and ST2 may be turned off. The first and second selection control signals SX1 and SX2 may be the same in the time periods T1 to T6. Thus, the first and second selection transistors ST1 and ST2 may be turned on or off simultaneously. The reverse selection control signal SXB may have an activation voltage and the reverse selection transistor SXT may be turned on. The reverse selection control signal SXB and the first selection control signal SX1 may have opposite phases. When the reverse selection transistor SXT is turned on, the first selection transistor ST1 may be turned off. When the reverse selection transistor SXT is turned off, the first selection transistor ST1 may be turned on. However, the embodiments of the present disclosure are not limited thereto. In some embodiments, in the first time period T1, the reverse selection control signal SXB may have a deactivation voltage and the reverse selection transistor SXT may be turned off.

FIG. 9 is an example of a timing diagram including a second period shown in FIG. 6. FIG. 10 is an equivalent circuit showing the operation of transistors in the second period.

Referring to FIGS. 9 and 10, in the second time period T2, the signals TX, SX1, and SX2 except for the reset control signal and the reverse selection control signal SXB may have deactivation voltages, respectively. The reset control signal RX and the reverse selection control signal SXB may have activation signals, respectively.

In the second time period T2, the transmission transistor TT and the first and second transistors ST1 and ST2 may be turned off. As the transmission transistor TT is turned off, photocharges are allowed to accumulate on the photodetector PD.

In some embodiments, in the second time period T2, the reset control signal RX and the reverse selection control signal SXB may have deactivation voltages, respectively.

FIG. 11 is a timing view including a third period shown in FIG. 6. FIG. 12 is a circuit view showing the operation of transistors in the third period.

Referring to FIGS. 11 and 12, in the third time period T3, the reset control signal RX and the reverse selection control signal SXB may have activation voltages, respectively, and the transmission control signal TX and the first and second selection control signals SX1 and SX2 may have deactivation voltages, respectively. In the third time period T3, the boosting control signal FDB may have no voltage. In the third time period T3, the reset transistor RT and the reverse selection transistor SXT may be turned on. The transmission transistor TT and the first and second selection transistors ST1 and ST2 may be turned off.

In the third time period T3, as the reset transistor RT is turned on, the voltage of the floating diffusion region FD may be reset to the power voltage VDD.

In some embodiments, the first and second selection control signals SX1 and SX2 may have activation voltages, respectively, and the reverse selection control signal SXB may have a deactivation voltage.

FIG. 13 is a timing view including a fourth period shown in FIG. 6. FIG. 14 is a circuit view showing the operation of transistors in the fourth period.

Referring to FIGS. 13 and 14, in the fourth time period T4, the selection control signal SX1 and SX2 may have an activation voltage, and the transmission control signal TX, the reverse selection control signal SXB, and the reset control signal RX may have deactivation voltages, respectively. In the fourth time period T4, the boosting control signal FDB may have no voltage. In the fourth time period T4, the first and second selection transistors ST1 and ST2 may be turned on, and the reset transistor RT, the reverse selection transistor SXT, and the transmission transistor TT may be turned off.

In the fourth time period T4, as the first and second selection transistors ST1 and ST2 are turned on, the voltage level of the floating diffusion region FD may read out. In the implementations, the output voltage output to the pixel signal Vout may vary based on the voltage of the floating diffusion region FD. Thus, based on the output voltage, the voltage of the floating diffusion region FD may be calculated. At this time, the driver transistor DT may operate as a source follower circuit.

Calculating the voltage of the floating diffusion region FD based on the output voltage may mean that the electrical signal transmitted from the driver transistor DT is output to the output signal line through the first selection transistor ST1 and the second selection transistor ST2.

Since the reverse selection transistor SXT is turned off in the fourth time period T4, the boosting control signal FDB is not applied to the boosting capacitor CFDB but parasitic capacitance may be formed between electrodes surrounding the boosting capacitor CFDB (e.g., one electrode and the other electrode). Since in the capacitance of the floating diffusion region FD, the extent to which the boosting capacitance of the boosting capacitor CFDB occupies is large, it is preferable to lower the capacitance of the boosting capacitor CFDB in the fourth time period T4.

According to one embodiment, the boosting capacitor CFDB may be disposed between the gate electrode of the driver transistor DT and the drain electrode (or source electrode) of the driver transistor DT, and so the boosting capacitor CFDB may be subject to the Miller Effect. The boosting capacitor CFDB subjected to the Miller Effect may have Miller capacitance. The Miller capacitance may be calculated by the following equation.

$$CP ( FDB\_M ) = CP ( FDB ) \times ( 1 - ASFG ) \qquad [ Equation ]$$

Here, CP(FDB) means the capacitance of the boosting capacitor CFDB (before the Miller Effect), CP(FDB_M) means Miller capacitance, and ASFG means a source follower gain. The source follower gain ASFG may be an inherent characteristic of the source follower circuit and may be rational number greater than 0 and less than 1. As discussed above, the driver transistor DT operates as the source follower circuit with the source follower gain ASFG in the fourth time period T4.

According to the above equation, the Miller capacitance CP(FDB_M) may be smaller than the capacitance CP(FDB) of the boosting capacitor CFDB with no Miller Effect. Accordingly, in the fourth time period T4, the capacitance of the boosting capacitor CFDB may be lowered, thereby implementing HCG mode.

In the fourth time period T4, the voltage of the floating diffusion region FD may be provided to the correlate double sampler (130, see FIG. 2).

FIG. 15 is an example of a timing diagram including a fifth period shown in FIG. 6. FIG. 16 is an equivalent circuit showing an operation of transistors in the fifth period.

Referring to FIGS. 15 and 16, in the fifth time period T5, the selection control signal SX1 and SX2 and the reset control signal RX may have deactivation voltages, respectively, and the transmission control signal TX and the reverse selection control signal SXB may have activation voltages, respectively. In the fifth time period T5, the boosting control signal FDB may have a predetermined voltage. In the fifth time period, the first and second selection transistors ST1 and ST2 and the reset transistor RT may be turned off, and the reverse selection transistor SXT and the transmission transistor TT may be turned on. The time period when the reverse control signal SXB is applied may be longer than the time period when the boosting control signal FDB is applied. The time period when the boosting control signal FDB is applied may be included in the time period when the reverse selection control signal SXB is applied, but the embodiments of the present disclosure are not limited thereto.

In the fifth time period T5, the transmission transistor TT and the reverse selection transistor SXT may be turned on, and the reset transistor RT and the first and second selection transistors ST1 and ST2 may be turned off. In the fifth time period T5, the photocharges of the photodetector PD may be moved to the floating diffusion region FD. Accordingly, the voltage of the floating diffusion region FD may vary based on the amount of the moved photocharges. also, as the movement of the photocharges is completed, the voltage of the floating diffusion region FD may have a voltage corresponding to the amount of the photocharges.

Meanwhile, the voltage of the floating diffusion region FD may be boosted by the boosting control signal before the photocharges enter (i.e., at the beginning of the fifth time period T5). Since the boosting control signal FDB may be provided to the other electrode of the boosting capacitor CFDB, the voltage of the floating diffusion region FD connected to one electrode of the boosting capacitor CFDB is boosted momentarily. As the voltage of the floating diffusion region FD is boosted, the potential of the floating diffusion region FD can be lowered. Since the potential of the floating diffusion region FD is lowered, it is possible to improve the lag of some photocharges in the photodetector PD when photocharges moved from the photodetector FD.

FIG. 15 is a timing view including a fifth period shown in FIG. 6. FIG. 16 is a circuit view showing the operation of transistors in the fifth period.

Referring to FIGS. 15 and 16, in the sixth time period T6, the selection control signals SX1 and SX2 have activation voltages, respectively, and the transmission control signal TX, the reverse selection control signal SXB, and the reset control signal RX may have deactivation voltages, respectively. In the sixth time period T6, the boosting control signal FDB may have no voltage. In the sixth time period T6, the first and second selection transistors ST1 and ST2 may be turned on, and the reset transistor RT, the reverse selection transistor SXT, and the transmission transistor TT may be turned off.

In the sixth time period T6, as the first and second selection transistors ST1 and ST2 are turned on, the voltage level of the floating diffusion region FD may read out. Specifically, the output voltage output to the pixel signal Vout may vary based on the voltage of the floating diffusion region FD. That is, based on the output voltage, the voltage of the floating diffusion region FD having accumulated photocharges may be calculated. At this time, the driver transistor DT may be operated as a source follower.

Similar to the description of the fourth time period, in the sixth time period T6, the boosting capacitor CFDB may be disposed between the gate electrode of the driver transistor DT and the drain electrode (or source electrode) of the driver transistor DT. Accordingly, the boosting capacitor CFDB may be subject to the Miller Effect. The capacitance of the boosting capacitor CFDB subjected to the Miller Effect may have Miller capacitance. Due to that, in the sixth time period T6, the capacitance of the boosting capacitor CFD may be lowered, thereby implementing HCG mode.

In the sixth time period T6, the voltage of the floating diffusion region FD may be provided to the correlate double sampler (130, see FIG. 2).

The correlate double sampler (130, see FIG. 2) may calculate the voltage difference between the floating diffusion region FD in the sixth time period T6 and the floating diffusion region FD in the fourth time period T4, and provide it to the ADC (140, see FIG. 2). The difference between the voltage of the floating diffusion region FD in the sixth time period T6 and the voltage of the floating diffusion region FD in the fourth period T4 may correspond to the amount of photocharges applied to the photodetector PD.

The image sensing device according to the embodiments of the present disclosure may be described as follows.

The image sensing device according to the embodiments of the present disclosure may include a driver transistor comprising one electrode to which a power voltage is applied, a gate electrode connected to a floating diffusion region, and the other electrode; a first selection transistor comprising one electrode connected to the other electrode of the driver transistor, a gate electrode to which a first selection control signal is applied, and the other electrode; a second selection transistor comprising one electrode connected to the other electrode of the first selection transistor, a gate electrode to which a second selection control signal is applied, and the other electrode connected to an output signal line; and a boosting capacitor between the other electrode of the first selection transistor and the floating diffusion region.

According to the embodiments, the first selection control signal and the second selection control signal may be the same.

According to the embodiments, the first selection transistor and the second transistor may be turned on or off simultaneously.

According to the embodiments, the image sensing device may further include a reverse selection transistor comprising one electrode connected to the other electrode of the first selection transistor, a gate electrode to which a reverse control signal is applied, and the other electrode to which a boosting control signal is applied.

According to the embodiments, when the first selection control signal has an activation voltage, the reverse selection control signal may have a deactivation voltage, and when the first selection control signal has a deactivation signal, the reverse selection control signal may have an activation voltage.

According to the embodiments, the application time of the reverse selection control signal may be longer than the application time of the boosting control signal.

According to the embodiments, the voltage of the floating diffusion region may be boosted when the boosting control signal is applied.

According to the embodiments, the capacitance of the boosting capacitor may decrease when the reverse selection transistor is turned off and the first selection transistor is turned on.

According to the embodiments, the boosting capacitor may have Miller capacitance when the reverse selection transistor is turned off and the first selection transistor is turned on.

According to the embodiments, the image sensing device may further include a reset transistor comprising one electrode connected to the electrode of the driver transistor, a gate electrode to which a reset control signal is applied, and the other electrode connected to the floating diffusion region.

According to the embodiments, the image sensing device may further include a transmission transistor comprising one electrode connected to a photodetector, a gate electrode to which a transmission control signal is applied, and the other electrode connected to the floating diffusion region.

According to the embodiments, a method of operating an image sensing device may include a first time period in which a reset transistor and a transmission transistor are turned on and a photodetector is reset; a second time period in which photocharges accumulate in the photodetector; a third time period in which a floating diffusion region is reset; a fourth time period in which a selection transistor is turned on, a reverse selection transistor is turned off, and the voltage of the reset floating diffusion region is output; a fifth time period in which the transmission transistor is turned on and the photocharges move to the floating diffusion region; and a sixth time period in which the selection transistor is turned on, the reverse selection transistor is turned off, and the voltage of the floating diffusion region where the photocharges accumulate is output.

According to the embodiments, the boosting control signal may be applied to a boosting capacitor between the floating diffusion region and the reverse selection transistor in the fifth time period.

According to the embodiments, the selection transistor may include a first selection transistor comprising one electrode connected to the other electrode of the driver transistor, a gate electrode to which a first selection control signal is applied, and the other electrode; and a second selection transistor comprising one electrode connected to the other electrode of the first selection transistor, a gate electrode to which a second selection control signal is applied, and the other electrode connected to an output signal line.

According to the embodiments, the first selection control signal and the second selection control signal may be the same.

According to the embodiments, the first selection transistor and the second selection transistor may be turned on and off simultaneously.

According to the embodiments, the reverse selection transistor may include one electrode connected to the other electrode of the first selection transistor; a gate electrode to which a reverse selection control signal is applied, and the other electrode to which the boosting control signal is applied.

According to the embodiments, when the first selection control signal has an activation voltage, the reverse selection control signal may have a deactivation voltage, and when the first selection control signal has a deactivation signal, the reverse selection control signal may have an activation voltage.

According to the embodiments, in the fifth time period, the application time of the reverse selection control signal may be longer than the application time of the boosting control signal.

According to the embodiments, the fifth time period, the boosting capacitor may have Miller capacitance.

While various embodiments have been described with reference to the exemplified drawings, variations and improvements of the disclosed embodiments and other embodiments may be made based on what is described or illustrated in this document.

1. An image sensing device, comprising:
a photoelectric conversion element configured to generate photocharges corresponding to an incident light;
a floating diffusion region coupled to the photoelectric conversion element and configured to receive and store the photocharges;
a driver transistor comprising a first electrode to which a power voltage is applied, a gate electrode connected to the floating diffusion region, and a second electrode;
a first selection transistor comprising a fourth electrode connected to the second electrode of the driver transistor, a gate electrode to which a first selection control signal is applied, and fifth electrode;
a second selection transistor comprising a sixth electrode connected to the fifth electrode of the first selection transistor, a gate electrode to which a second selection control signal is applied, and a seventh electrode connected to an output signal line; and
a boosting capacitor disposed between the fifth electrode of the first selection transistor and the floating diffusion region and configured to control a capacitance of the floating diffusion region.

2. The image sensing device of claim 1, wherein the first selection control signal and the second selection control signal are the same as each other.

3. The image sensing device of claim 1, wherein the first selection transistor and the second selection transistor are turned on or off simultaneously.

4. The image sensing device of claim 1, further comprising:
a reverse selection transistor comprising an eighth electrode connected to the fifth electrode of the first selection transistor, a gate electrode to which a reverse selection control signal is applied, and a ninth electrode to which a boosting control signal is applied.

5. The image sensing device of claim 4, wherein in response to the first selection control signal having an activation voltage, a reverse selection control signal has a deactivation voltage, and in response to the first selection control signal having a deactivation signal, the reverse selection control signal has an activation voltage.

6. The image sensing device of claim 4, wherein an application time of the reverse selection control signal is longer than an application time of the boosting control signal.

7. The image sensing device of claim 4, wherein in response to an application of the boosting control signal, a voltage of the floating diffusion region increases.

8. The image sensing device of claim 4, wherein a capacitance of the boosting capacitor decreases in response to the reverse selection transistor being turned off and the first selection transistor being turned on.

9. The image sensing device of claim 4, wherein the boosting capacitor has a Miller capacitance due to a Miller effect caused by the driver transistor operating as a source follower circuit with a source follower gain, in response to the reverse selection transistor being turned off and the first selection transistor being turned on.

10. The image sensing device of claim 1, further comprising:
a reset transistor comprising a tenth electrode connected to the first electrode of the driver transistor, a gate electrode to which a reset control signal is applied, and an eleventh electrode connected to the floating diffusion region.

11. The image sensing device of claim 1, further comprising:
a transmission transistor comprising a twelfth electrode connected to a photodetector, a gate electrode to which a transmission control signal is applied, and a thirteenth electrode connected to the floating diffusion region.

12. A method of operating an image sensing device, comprising:
turning on a reset transistor and a transmission transistor and resetting a photodetector in a first time period;
operating, in a second time period, a photodetector to generate and accumulate photocharges in the photodetector corresponding to an incident light;
resetting a floating diffusion region in a third time period;
operating, in a fourth time period, at least one selection transistor and a reverse selection transistor in a fourth time period to output a voltage of the floating diffusion region which has been reset;
operating, in a fifth time period, the transmission transistor to allow the photocharges to move from the photodetector to the floating diffusion region; and
in a sixth time period, operating the at least one selection transistor and turning off the reverse selection transistor to output the voltage of the floating diffusion region to which the photocharges are transferred from the photodetector.

13. The method of claim 12, further comprising applying, in the fifth time period, a boosting control signal to a boosting capacitor between the floating diffusion region and the reverse selection transistor.

14. The method of claim 12, wherein the at least one selection transistor comprises:
a first selection transistor electrically connected to a driver transistor and; and
a second selection transistor electrically connected to the first selection transistor.

15. The method of claim 14, further comprising: applying a first selection control signal and a second selection control signal to the first selection transistor and the second selection transistor, respectively, and wherein the first selection control signal and the second selection control signal are the same as each other.

16. The method of claim 14, wherein the first selection transistor and the second selection transistor are turned on and off simultaneously.

17. The method of claim 15, wherein the reverse selection transistor is electrically connected to the first selection transistor, and the method further comprises applying a reverse selection control signal and a boosting control signal to the reverse selection transistor.

18. The method of claim 17, further comprising: applying a first selection control signal and a second selection control signal to the first selection transistor and the second selection transistor, respectively, and wherein when the first selection control signal has an activation voltage, the reverse selection control signal has a deactivation voltage, and when the first selection control signal has a deactivation signal, the reverse selection control signal has an activation voltage.

19. The method of claim 17, wherein in the fifth time period, an application time of the reverse selection control signal is longer than an application time of the boosting control signal.

20. The method of claim 17, wherein in the fifth time period, a boosting capacitor disposed to connect the floating diffusion region has Miller capacitance due to a Miller effect caused by the driver transistor operating as a source follower circuit with a source follower gain.
